(19) United States
(12) Patent Application Publication
(10) Pub. No.: US 2024/0357927 A1
(43) Pub. Date: Oct. 24, 2024

(54) Light Emitting Electrochemical Cell

(71) Applicants: Latvian Institute of Organic Synthesis, Riga (LV); Institute of Solid State Physics, University of Latvia, Riga (LV)

(72) Inventors: Kaspars Leduskrasts, Riga (LV); Edgars Suna, Riga (LV); Aivars Vembris, Riga (LV); Adriana Maurucaite, Tukums (LV)

(21) Appl. No.: 18/039,178

(22) PCT Filed: Nov. 25, 2022
(86) PCT No.: PCT/IB2022/061411

§ 371 Date: May 26, 2023

(30) Foreign Application Priority Data
Aug. 4, 2022 (LV) LVP2022000067

(51) Int. Cl. H10K 85/60; C09K 11/06; H10K 50/135; H10K 85/10; H10K 102/00

(52) U.S. Cl. CPC H10K 85/6572; C09K 11/06; H10K 85/1135; H10K 85/141; H10K 85/654; C09K 2211/1018; H10K 50/135; H10K 2102/351

(57) ABSTRACT

The present invention relates to multi-layered light emitting electrochemical cell (LEC) and preparation thereof. The present invention also relates to the composition of the light emitting layer (3) of a light emitting electrochemical cell (LEC). The light emitting layer (3) of the light emitting electrochemical cell consists of a neutral polymer and a pyridinium luminophore. The pyridinium luminophores used are non-polymeric small molecule compounds.

### TECHNICAL FIELD

The present invention relates to light emitting electrochemical cell and preparation thereof. The present invention also relates to the composition of the light emitting layer of a light emitting electrochemical cell.

### BACKGROUND ART

Electroluminescence (EL) is a process by which a spontaneous light emission occurs after the combination of an electron and a hole [1]. Light emitting devices based on the EL process are light-weighted, thin, highly efficient and occasionally flexible. [2] Generally, the architecture of EL based light emitting devices is complex, consisting of multiple layers: hole injection layer, hole transport layer, light emitting layer, electron transport layer, electron injection layer etc. [3]. Moreover, each of the aforementioned layers are extremely thin imposing difficulties in the manufacture process of EL based devices.

Light emitting electrochemical cell (LEC) is the simplest EL based device type. LECs consist of a single active layer placed between and anode and a cathode [4]. The active layer of LEC usually consists of a light emitting material mixed with an electrolyte. Purely organic light emitting materials offer a cheaper, less toxic and more structurally diverse alternative to commonly used heavy metal (e.g. Ir) based light emitting materials [5]. As such LECs based on purely organic light emitting materials would be the most suitable EL based device for mass production and commercialization.

To be commercially viable LEC devices must overcome several drawbacks associated with the aforementioned simplified design, specifically: emission efficiency, color, turn-on time and operational stability. The aforementioned device parameters are to a large degree dependent on the materials used in the light emitting layer of a LEC device [6]. The light emitting layer of a LEC device usually consists of (I) a light emitting species (luminophore) and (II) ionic additives. The luminophore is responsible for light emission and the ionic additives for the charge balance in the device.

Small molecule (SM) purely organic luminophores is one class of compounds used in LEC light emitting layers. In particular, ionic SM purely organic luminophores based on imidazolium luminophores are widely used in LEC design [7]. In contrast, LECs based on pyridnium luminophores are rare.

Su et. al. reported a pyridinium luminophore based orange-red LEC [8]. The pyridinium fragment was substituted at positions 1, 2 and 4. Besides the pyridinium-based luminophore the emitting layer consisted of an additional ionic component—BMIM⁺ (PF₆)⁻.

Despite a prior art employing pyridinium luminophores in their emitting layer there is a need for improved and alternative SM purely organic compounds for the use in LECs. In particular, light emitting layer composition of a LEC can be simplified by the use of charged luminophores that maintain the device functionality without the need for additional ionic components.

### DESCRIPTION OF THE INVENTION

The present invention is a multi-layered LEC, with:
a light emitting layer, comprised of
   (I) a purely organic SM pyridinium-based luminophore;
   (II) neutral polymer,
an anode,
a cathode.

An example of purely organic SM pyridinium based luminophore according to formula 1 is:

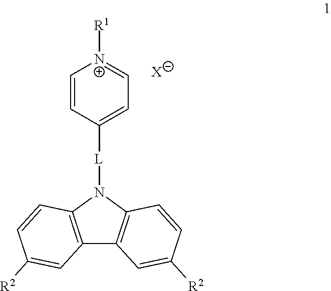

wherein
R¹ is an aliphatic group bonded to the pyridinium moiety at position 1;
R² is a neutral or electron donating substituent of the carbazole core;
L is an aromatic linker;
X is a negatively charged counter ion.

An example of neutral polymer is poly(methyl 2-methylpropenoate) (PMMA) and poly(ethylene oxide) (PEO).

An example of anode is indium tin oxide (ITO), or alternatively other transparent metal oxides. The anode layer can be optionally covered with poly(3,4-ethylenedioxythiophene) polystyrene sulfonate (PEDOT:PSS) layer.

An example of cathode is aluminium (Al), or alternatively other highly conductive materials.

### DETAILED DESCRIPTION OF THE INVENTION

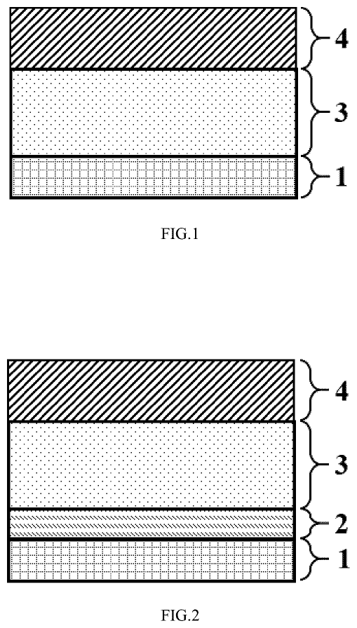

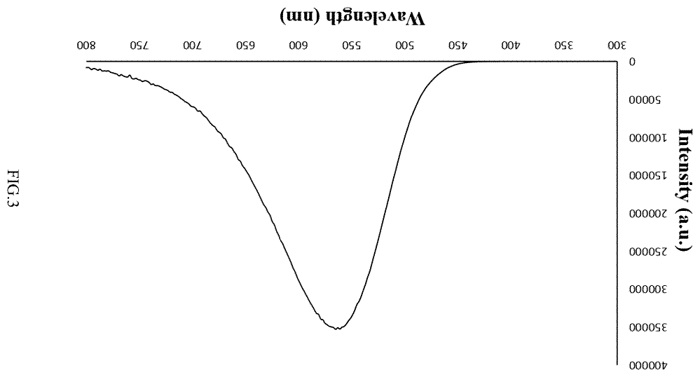

The LEC consists of light emitting layer (layer 3) sandwiched between a transparent anode layer (layer 1) and a highly conductive cathode layer (layer 4). Optionally the surface of the anode layer (layer 1) can be smoothened by an optional addition of a PEDOT:PSS layer (layer 2). Accordingly, the order of layers is either 1, 3, 4 (FIG. 1) or 1, 2, 3, 4 (FIG. 2).

The light emitting layer (layer 3) can have thickness between 80 to 400 nm. The light emitting layer consists of an emissive pyridinium luminophore and a neutral polymer. The pyridinium luminophore comprises 70 to 100 wt % of the emitting layer, inversely the neutral polymer, for example PMMA or PEO, comprises 30 to 0 wt % of the emitting layer.

The light emitting layer (layer 3) can be wet-casted or spin-coated using acetonitrile, chloroform, dichloromethane, methanol, dimethyl sulfoxide and mixtures thereof or other organic solvents. For example, the spin-coating of a 90 wt % of a pyridinium luminophore and 10 wt % of neutral polymer with a total concentration of 20 mg/mL in acetonitrile was spin coated with speed/acceleration of 2000/2000 rpm, to achieve a light emitting layer (layer 3) with thickness of about 200 nm. Afterwards the sample was heated at 110° C. for 15 minutes.

The light emitting layer (layer 3) was either directly wet-casted or spin-coated onto ITO (layer 1), or any other transparent metal oxide, or alternatively to achieve a smoother ITO surface, the transparent metal oxide (layer 1) can be covered with a layer of PEDOT:PSS (layer 2). The thickness of PEDOT:PSS layer (layer 2) can vary between 20 and 70 nm. For example, spin coating of a water solution of 1.5 wt % PEDOT:PSS with rotation speed/acceleration 2000/2000 rpm was used to achieve about 40 nm thick layer 2. Then the sample was heated at 125° C. for 20 minutes.

The cathode layer (layer 4) was deposited onto the light emitting layer (layer 3) through thermal evaporation in vacuum. The cathode layer (layer 4), comprised of Al or any other highly conductive material, can have thickness between 40 and 200 nm. For example, Al electrode deposition by thermal evaporation in vacuum at the speed of 5 angstroms/see in a pressure lower than 2×10⁻⁶ mBar, resulted in layer 4 thickness of 120 nm.

The light emitting species in the LEC device light emitting layer is a purely organic SM pyridinium luminophore.

For example a purely organic SM pyridinium luminophore according to formula 1:

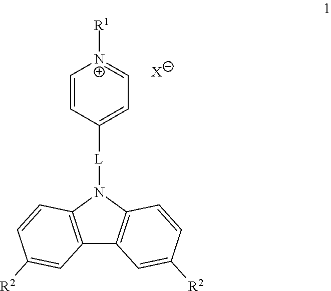

wherein
R¹ is an aliphatic carbon chain bonded to the pyridinium moiety at position 1. The term “aliphatic carbon chain” refers to a straight or branched hydrocarbon chain containing between 1 and 12 carbon atoms with an optional terminal substituent. Terminal substituent refers to a substituent attached at the end of the aliphatic carbon chain. For example —(CH₂)ₙ—CH₂R³, where n=0 to 11, and R³ is a terminal substituent, such —H, -Me, —COO⁻, —CN, -Ph.
R² is a neutral or electron donating substituent that complements the carbazole core. The term “neutral or electron rich substituent” refers to a substituent that is characterized by Hammett σₚₐᵣₐ constants in the range between −0.90 and 0.23. Such as —H, -Me, -tBu, -Ph, —OMe, —NMe₂, —NPh₂, —NH₂, —OH, —SiMe₃ or alternatively the carbazole can be replaced with a larger condensed moiety. The term “larger condensed moiety” refers to a dibenzo[a,g]carbazole, dibenzo[b,g]carbazole, dibenzo[c,g]carbazole, dibenzo[a,h]carbazole, dibenzo[b,h]carbazole, dibenzo[c,h]carbazole, dibenzo[a,i]carbazole, dibenzo[b,i]carbazole or dibenzo[c,i]carbazole.
L is an aromatic linker. The term “aromatic linker” refers to a disubstituted aromatic moiety that contains a carbazole moiety at one position and a pyridinium moiety at the other. Such as 1,4-phenylene, 2,6-naphtalene, 1,4-naphtalene.
X is a negatively charged counter ion NO₃⁻, MsO⁻, ClO₄⁻, Cl⁻.

Synthesis of pyridinium luminophores follow the general Scheme 1:

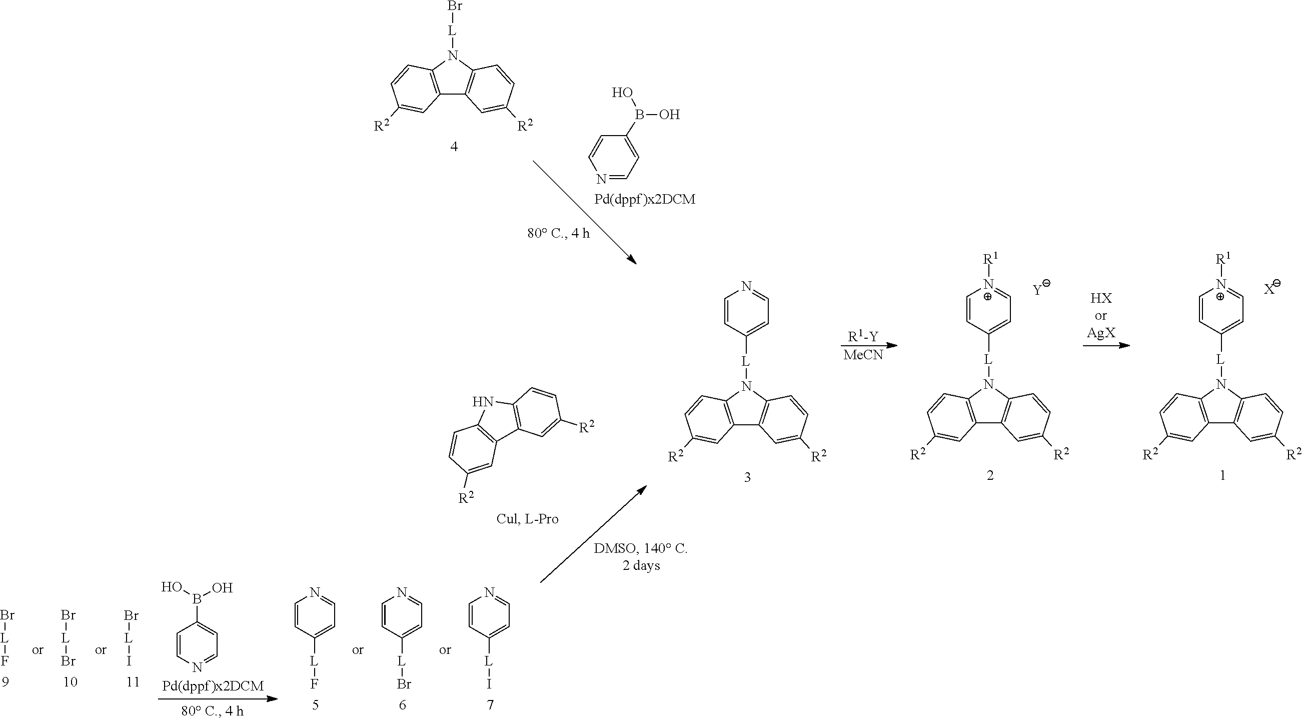

wherein the building blocks 4 in a Suzuki-Miyaura reaction with pyridine 4-boronic acid affords compounds with general formula 3.

Alternatively bromides 9, 10, 11 in a Suzuki-Miyaura reaction with pyridine 4-boronic acid gives halogenides 5, 6 and 7. Subsequent Ullmann coupling for compounds 6 and 7, or S_{N}Ar reaction for compound 5, with 3,6-disubstituted carbazoles 8 form compounds with general formula 3.

Pyridines with general formula 3 were alkylated with R¹—Y, where Y is selected from Cl, Br, I, OMs, OTs, OTf in MeCN to form pyridinium salts 2. Optionally the formed counter ion Y⁻ (for example I⁻) in compounds 2 was exchanged to X⁻ to form pyridinium salts 1, through the use of reversed phase column chromatography with HX added to the eluent or by the use of AgX salts, thus performing counterion metathesis.

For example 1.00 equivalents of the commercially available 9-(4-bromophenyl)-9H-carbazole 4a, 1.05 equivalents of pyridine 4-boronic acid, 0.05 equivalents of Pd(dppf)×2CH₂Cl₂ and 3.0 equivalents of K₂CO₃ in a refluxing MeCN:H₂O—6:1 mixture reacted to afford 9-(4-(pyridin-4-yl)phenyl)-9H-carbazole 3a in a 75% yield after purification with column chromatography.

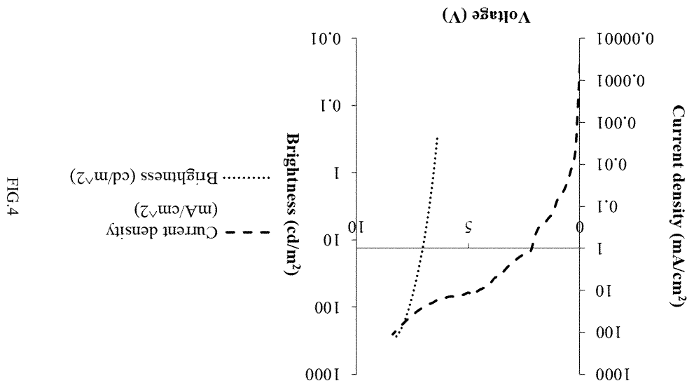

The compound 3a was methylated with Mel in MeCN to give the pyridinium iodide 2a, and afterwards treated with AgClO₄ to afford the compound 1a in a 93% yield after two steps. The emission spectra of the spin coated film is visible in FIG. 3.

### Compound 1a:

¹H NMR (400 MHz, (CD₃)₂SO, δ): 9.00-8.95 (m, 2H), 8.56-8.51 (m, 2H), 8.37-8.32 (m, 2H), 8.29-8.24 (m, 2H), 7.94-7.89 (m, 2H), 7.54-7.45 (m, 4H), 7.36-7.31 (m, 2H), 4.35 (s, 3H) ppm.

¹³C NMR (101 MHz, (CD₃)₂SO, δ): 153.7, 145.9, 140.6, 139.8, 132.4, 130.3, 127.5, 126.9, 124.4, 123.5, 121.1, 121.0, 110.1, 47.5 ppm.

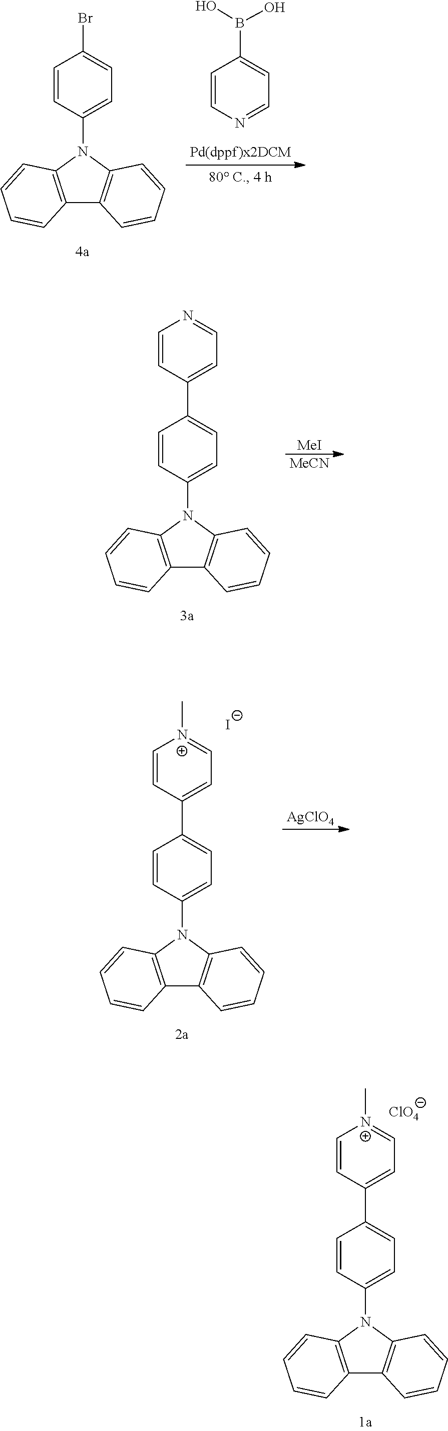

Alternatively compound 3a was alkylated with BuBr in MeCN to afford the pyridinium bromide 2b, which after treatment with AgClO₄ afforded the pyridinium perchlorate 1b in an 86% yield after two steps.

### Compound 1b:

¹H NMR (400 MHz, (CD₃)₂SO, δ): 9.08-9.03 (2H, m), 8.57-8.52 (2H, m), 8.36-8.31 (2H, m), 8.28-8.23 (2H, m), 7.95-790 (2H, m), 7.55-7.44 (4H, m), 7.37-7.30 (2H, m), 4.59 (2H, t, J=7.2 Hz), 1.99-1.88 (2H, m), 1.39-1.28 (2H, m), 0.93 (3H, t, J=7.2 Hz) ppm.

¹³C NMR (101 MHz, (CD₃)₂SO, δ): 154.2, 145.1, 140.7, 139.9, 132.4, 130.4, 127.6, 127.0, 124.9, 123.5, 121.2, 121.1, 110.1, 60.3, 32.9, 19.2, 13.7 ppm.

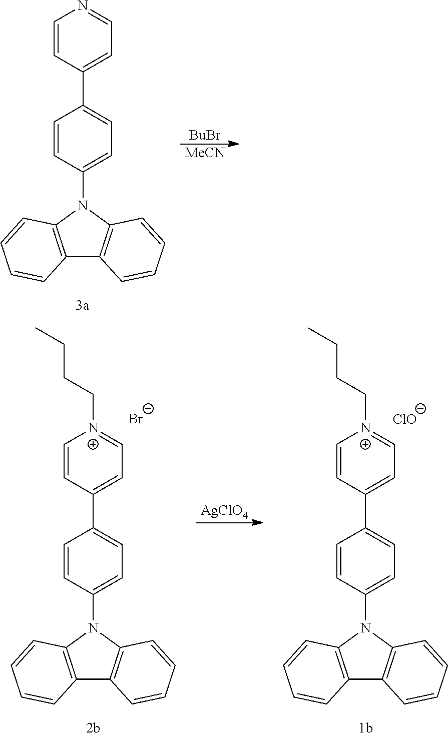

In the alternative route 1.00 equivalents of commercially available 1,4-dibromobenzene 10, 1.00 equivalents of pyridine 4-boronic acid, 0.05 equivalents of Pd(dppf)×2CH₂Cl₂ and 3.0 equivalents of K₂CO₃ in a refluxing MeCN:H₂O—6:1 mixture reacted to afford 4-(4-bromophenyl)pyridine 6 in a 38% yield after purification with column chromatography. Compound 6 in an CuI/L-Proline catalyzed Ullmann type reaction in the presence of K₂CO₃ formed pyridine 3c in a 79% yield after purification with column chromatography. Subsequent alkylation with Mel and ion exchange with AgClO₄ resulted in pyridinium salts 2c and 1c respectively, with an overall yield of 75% over two steps.

### Compound 1c:

¹H NMR (400 MHz, (CD₃)₂SO, δ): 8.99-8.94 (2H, m), 8.75-8.70 (2H, m), 8.56-8.51 (2H, m), 8.38-8.32 (2H, m), 8.00-7.95 (2H, m), 7.85-7.79 (6H, m), 7.63-7.59 (2H, m), 7.53-7.47 (4H, m), 7.39-7.32 (2H, m), 4.35 (3H, s) ppm.

¹³C NMR (101 MHz, (CD₃)₂SO, δ): 153.8, 145.9, 140.8, 140.5, 139.9, 133.6, 132.5, 129.4, 127.4, 127.3, 127.1, 126.0, 124.5, 124.4, 119.4, 110.8, 47.6 ppm.

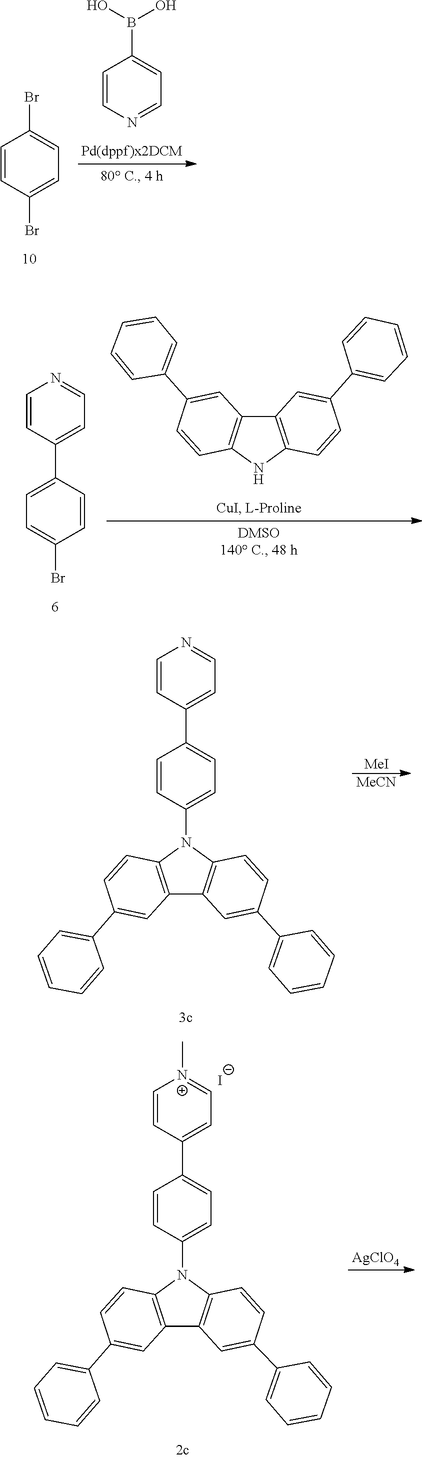

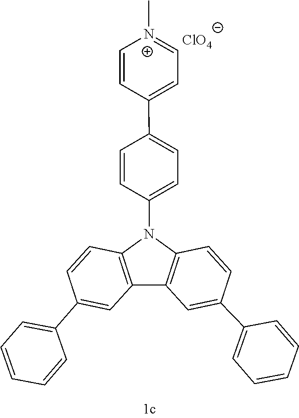

Alternatively compound 3c was alkylated with BuBr in MeCN to afford the pyridinium bromide 2d, which after treatment with AgClO₄ afforded the pyridinium perchlorate 1d in a 70% yield after two steps.

### Compound 1d:

¹H NMR (400 MHz, (CD₃)₂SO, δ): 9.09-9.02 (2H, m), 8.75-8.70 (2H, m), 8.56-8.51 (2H, m), 8.38-8.32 (2H, m), 7.99-7.91 (2H, m), 7.85-7.77 (6H, m), 7.63-7.57 (2H, m), 7.53-7.46 (4H, m), 7.39-7.32 (2H, m), 4.58 (2H, t, J=7.4 Hz), 1.94 (2H, quintet, J=7.4 Hz), 1.34 (2H, sextet, J=7.4 Hz), 0.94 (3H, t, J=7.4 Hz) ppm.

¹³C NMR (101 MHz, (CD₃)₂SO, δ): 154.1, 145.0, 140.8, 140.5, 139.8, 133.6, 132.4, 130.5, 129.4, 127.4, 127.3, 127.1, 126.0, 124.9, 124.5, 119.4, 110.8, 60.3, 32.9, 19.2, 13.7 ppm.

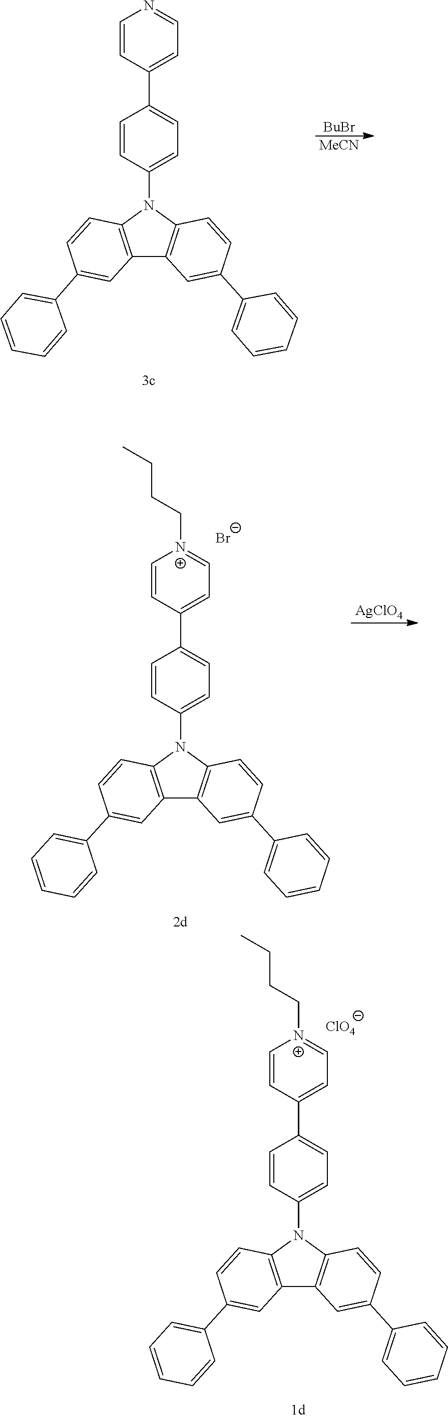

Using the previously described routes other compounds were synthesized. For example, compounds 1e, 1f, 1g, 1h, 1i etc.

### Compound 1e:

¹H NMR (400 MHz, (CD₃)₂SO, δ): 9.07-9.02 (2H, m), 8.56-8.51 (2H, m), 8.36-8.27 (4H, m), 7.93-7.87 (2H, m), 7.54-7.49 (2H, m), 7.48-7.43 (2H, m), 4.58 (2H, t, J=7.4 Hz), 1.98-1.89 (2H, m), 1.40 (18H, s), 1.39-1.28 (2H, m), 0.93 (3H, t, J=7.4 Hz) ppm.

¹³C NMR (101 MHz, (CD₃)₂SO, δ): 154.2, 145.0, 143.8, 141.2, 138.2, 131.8, 130.4, 127.0, 124.8, 124.4, 123.7, 117.2, 109.7, 60.3, 34.9, 32.9, 32.1, 19.2, 13.7 ppm.

### Compound 1f

¹H NMR (400 MHz, (CD₃)₂SO, δ): 8.97-8.92 (2H, m), 8.54-8.50 (2H, m), 8.34-8.28 (4H, m), 7.93-7.87 (2H, m), 7.54-7.49 (2H, m), 7.48-7.43 (2H, m), 4.33 (3H, s), 1.40 (18H, s) ppm.

¹³C NMR (101 MHz, (CD₃)₂SO, δ): 153.8, 145.9, 143.8, 141.2, 138.2, 131.8, 130.3, 127.0, 124.4, 123.7, 117.2, 109.7, 47.5, 34.9, 32.1 ppm.

### Compound 1g:

¹H NMR (400 MHz, (CD₃)₂SO, δ): 9.10-9.06 (2H, m), 8.42-8.38 (2H, m), 8.34-8.30 (2H, m), 8.03-7.98 (1H, m), 7.97-7.90 (2H, m), 7.72-7.66 (1H, m), 7.55-7.49 (1H, m), 7.42-7.36 (2H, m), 7.35-7.30 (2H, m), 7.18-7.14 (1H, m), 6.98-6.93 (2H, m), 4.44 (3H, s) ppm.

¹³C NMR (101 MHz, (CD₃)₂SO, δ): 155.6, 145.8, 141.8, 135.8, 135.2, 131.4, 130.7, 129.0, 128.9, 128.8, 128.4, 126.8, 125.8, 123.7, 123.1, 121.1, 120.7, 110.1, 48.0 ppm.

### Compound 1h:

¹H NMR (400 MHz, (CD₃)₂SO, δ): 9.13-9.07 (2H, m), 9.01-8.96 (2H, m), 8.57-8.52 (2H, m), 8.40-8.34 (2H, m), 8.16-8.11 (2H, m), 8.02-7.97 (2H, m), 7.96-7.92 (2H, m), 7.80-7.73 (2H, m), 7.67-7.62 (2H, m), 7.61-7.55 (2H, m), 4.36 (3H, s) ppm.

¹³C NMR (101 MHz, (CD₃)₂SO, δ): 153.8, 146.0, 139.5, 137.4, 133.8, 130.4, 130.3, 129.7, 129.2, 128.6, 127.8, 126.4, 124.8, 124.7, 124.3, 117.3, 112.0, 47.6 ppm.

### Compound 1i:

¹H NMR (400 MHz, (CD₃)₂SO, δ): 9.00-8.94 (2H, m), 8.86-8.82 (1H, m), 8.63-8.57 (2H, m), 8.40-8.36 (1H, m), 8.33-8.24 (4H, m), 8.22-8.17 (1H, m), 7.90-7.84 (1H, m), 7.53-7.43 (4H, m), 7.36-7.30 (2H, m), 4.35 (3H, s) ppm.

¹³C NMR (101 MHz, (CD₃)₂SO, δ): 154.4, 145.9, 140.3, 137.0, 135.4, 132.0, 131.8, 131.6, 129.9, 129.2, 126.9, 126.4, 125.4, 124.7, 124.6, 123.4, 121.0, 120.9, 110.1, 47.5 ppm.

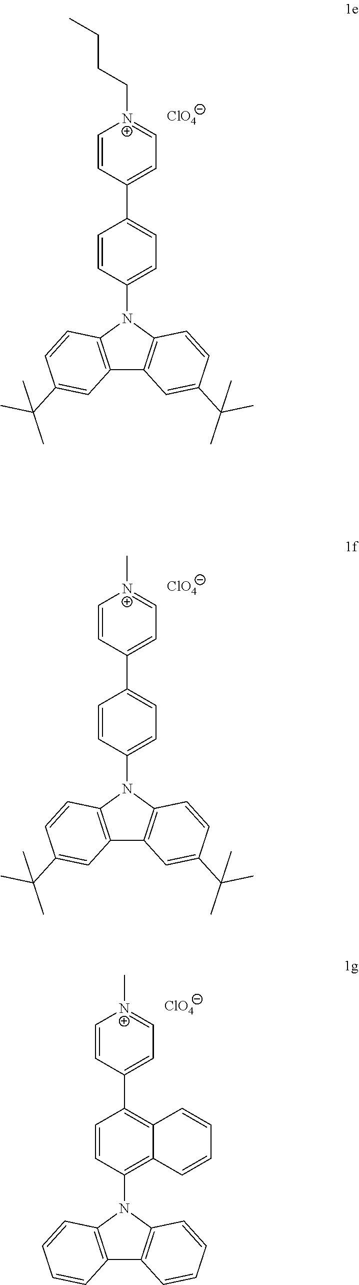

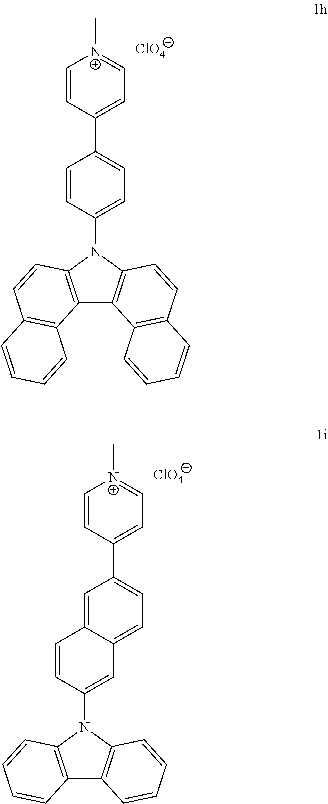

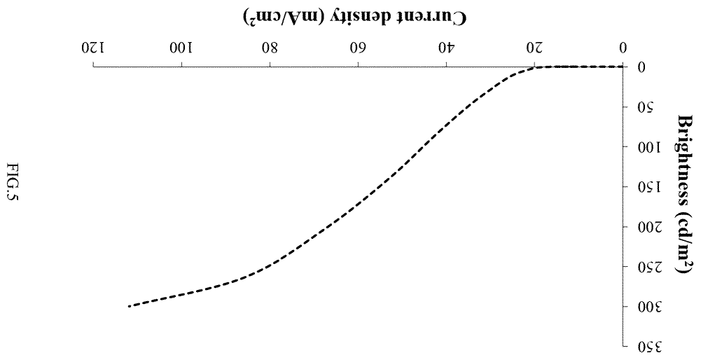

A typical LEC with emitting layer consisting of ITO/PEDOT:PSS(50 nm)/1a:PMMNA—9:1 (200 nm)/Al (120 nm) reached maximum current efficiency of 6.08 cd/A and power efficiency of 3.28 lm/W. The turn on time (time necessary to reach maximum brightness) for the device at 6 V was 80 seconds. Maximum brightness achieved for the device was 300 cd/m² (FIG. 4, FIG. 5).

### REFERENCES

1) C. W. Tang and S. A. VanSlyke, Appl. Phys. Lett., 1987, 51, 913-916.
2) Zou, S.-J.; Shen, Y.; Xie, F.-M.; Chen, J.-D.; Li, Y.-Q.; Tang, J.-X. Materials Chemistry Frontiers 2020, 4, 788-820.
3) Sudheendran S. S.; Dubey, D. K.; Shahnawaz; Yadav, R. A.; Nagar, M. R.; Sharma, A.; Tung, F. C.; Jou, J. H. Advanced Science 2020, 8, 2002254.
4) Q. Pei, G. Yu, C. Zhang, Y. Yang and A. J. Heeger, Science 1995, 269, 1086-1089.
5) C.-C. Ho, H.-F. Chen, Y.-C. Ho, C.-T. Liao, H.-C. Su and K.-T. Wong, Phys. Chem. Chem. Phys. 2011, 13, 17729-17736.
6) Fresta, E.; Costa, R. D. Journal of Materials Chemistry C 2017, 5, 5643-5675.
7) a) Kanagaraj, S.; Puthanveedu, A.; Choe, Y. Advanced Functional Materials 2019, 30, 1907126; b) Matsuki, K.; Pu, J.; Takenobu, T. Advanced Functional Materials 2020, 30, 1908641.
8) Shen, H.-L.; Hsiao, P.-W.; Yi, R.-H.; Su, Y.-H.; Chen, Y.; Lu, C.-W.; Su, H.-C. Dyes and Pigments 2022, 203, 110346.

1. A multi-layered light emitting electrochemical cell (LEC) comprising
a light emitting layer, the light emitting layer being placed between
a transparent anode layer entirely covering said light emitting layer (3), and
a cathode layer;
wherein the light emitting layer comprises a pyridinium luminophore.

2. The multi-layered light emitting electrochemical cell according to claim 1, wherein the light emitting layer further comprises a neutral polymer.

3. The multi-layered light emitting electrochemical cell according to claim 2, wherein the neutral polymer is poly(methyl methacrylate) or poly(ethylene oxide).

4. The multi-layered light emitting electrochemical cell according to claim 1, wherein the pyridinium luminiphore is a compound of Formula 1: 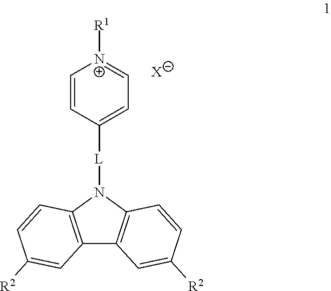
wherein
R¹ is an aliphatic group;
R² is a neutral or electron donating substituent of the carbazole core with a Hammett σₚₐᵣₐ constant in the range between −0.90 and 0.23;
L is an aromatic linker; and
X is a negatively charged counter ion selected from NO₃⁻, MsO⁻, ClO₄⁻, and Cl⁻.

5. The multi-layered light emitting electrochemical cell according to claim 1, further comprising a poly(3,4-ethylenedioxythiophene) polystyrene sulfonate layer placed between the light emitting layer and the transparent anode layer.

6. The multi-layered light emitting electrochemical cell according to claim 5, wherein the thickness of the poly(3,4-ethylenedioxythiophene) polystyrene sulfonate layer is 20 to 70 nm.

7. The multi-layered light emitting electrochemical cell according to claim 1, wherein the light emitting layer is 80 to 400 nm thick.

8. The multi-layered light emitting electrochemical cell according to claim 1, wherein the pyridinium luminophore is 70 to 100 wt % of the light emitting layer.

9. The multi-layered light emitting electrochemical cell according to claim 2, wherein the neutral polymer is 30 to 0 wt % of the light emitting layer.

10. The multi-layered light emitting electrochemical cell according to claim 1, wherein the light emitting layer is wet-casted or spin-coated directly onto the anode layer.

11. The multi-layered light emitting electrochemical cell (LEC) according to claim 1, wherein the cathode layer is deposited onto the light emitting layer through thermal evaporation in vacuum.
